(19) United States
(12) Patent Application Publication
(10) Pub. No.: US 2019/0326416 A1
(43) Pub. Date: Oct. 24, 2019

(54) MATERIAL COMBINATIONS FOR POLISH STOPS AND GATE CAPS

(71) Applicant: GLOBALFOUNDRIES Inc., Grand Cayman (KY)

(72) Inventors: Haigou Huang, Rexford, NY (US); Jiehui Shu, Clifton Park, NY (US); Chih-Chiang Chang, Clifton Park, NY (US); Xingzhao Shi, Ballston Lake, NY (US); Jinsheng Gao, Clifton Park, NY (US); Huy Cao, Rexford, NY (US)

(21) Appl. No.: 15/956,306

(22) Filed: Apr. 18, 2018

(51) Int. Cl. H01L 29/66; H01L 29/78

(52) U.S. Cl. CPC H01L 29/66734; H01L 29/66719; H01L 29/6656; H01L 29/7813

(57) ABSTRACT

Structures for a field-effect transistor and methods of forming a structure for field-effect transistor. A gate electrode is arranged in a lower portion of a trench in an interlayer dielectric layer, and a liner is formed inside an upper portion of the trench and over a top surface of the interlayer dielectric layer. A dielectric material is deposited in in the upper portion of the trench and over the liner on the top surface of the interlayer dielectric layer. The dielectric material is polished with a polishing process to remove the dielectric material from the liner on the top surface of the interlayer dielectric layer and to form a cap comprised of the dielectric material in the upper portion of the trench. The liner on the interlayer dielectric layer operates as a polish stop during the polishing process.

### BACKGROUND

The present invention relates to semiconductor device fabrication and integrated circuits and, more specifically, to structures for a field-effect transistor and methods of forming a structure for field-effect transistor.

Device structures for a field-effect transistor generally include a body region, a source and a drain defined in the body region, and a gate structure configured to apply a control voltage that switches carrier flow in a channel formed in the body region. When a control voltage that is greater than a designated threshold voltage is applied, carrier flow occurs in the channel between the source and drain to produce a device output current.

Contacts may provide vertical electrical connections to features of semiconductor devices, such as the gate structure and source/drain regions of a field-effect transistor. Self-aligned contacts (SAC) are formed in contact openings that are constrained during etching by the configuration of adjacent structures, e.g., sidewall spacers on adjacent gate structures, as opposed to being constrained by a patterned resist. For example, a self-aligned contact may be formed in a contact opening that is defined by selectively etching one material, e.g., silicon dioxide, of an interlayer dielectric layer relative to other materials, such as silicon nitride caps on adjacent gate structures. The formation of the silicon nitride caps involves the deposition of a layer of silicon nitride over the gate structures and interlayer dielectric layer, followed by a chemical-mechanical polish that removes the deposited silicon nitride from over the interlayer dielectric layer. Due to poor selectivity between silicon dioxide and silicon during the chemical-mechanical polish, gate heights and within-wafer uniformity may exhibit a large variation.

Improved structures for a field-effect transistor and methods of forming a structure for field-effect transistor are needed.

### SUMMARY

In an embodiment of the invention, a method includes forming a gate electrode arranged in a lower portion of a trench in an interlayer dielectric layer, forming a liner inside an upper portion of the trench and over a top surface of the interlayer dielectric layer, and depositing a dielectric material in an upper portion of the trench and over the liner on the top surface of the interlayer dielectric layer. The dielectric material is polished with a polishing process to remove the dielectric material from the liner on the top surface of the interlayer dielectric layer and to form a cap comprised of the dielectric material in the upper portion of the trench. The liner on the interlayer dielectric layer operates as a polish stop during the polishing process.

In an embodiment of the invention, a structure includes a semiconductor substrate, an interlayer dielectric layer including a trench extending to the semiconductor substrate, and a gate electrode in a lower portion of the trench. The structure further includes a liner in an upper portion of the trench over the gate electrode, and a dielectric cap in the upper portion of the trench over the liner.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-6 are cross-sectional views of a portion of a substrate at successive fabrication stages of a processing method for forming a structure in accordance with embodiments of the invention.

FIGS. 7-8 are cross-sectional views of a portion of a substrate at successive fabrication stages of a processing method for forming a structure in accordance with alternative embodiments of the invention.

### DETAILED DESCRIPTION

With reference to FIG. 1 and in accordance with embodiments of the invention, a semiconductor substrate 10 is provided that may be a bulk substrate or a device layer of a semiconductor-on-insulator (SOI) substrate. Gate structures 12 are arranged on a top surface of the semiconductor substrate 10. Each gate structure 12 includes a gate dielectric 16 and a gate electrode 18 with a top surface 15. Sections of an interlayer dielectric layer 14 are located in the gaps between the gate structures 12. Sidewall spacers 20 are arranged between the vertical sidewalls of the gate structures 12 and the sections of the interlayer dielectric layer 14.

The interlayer dielectric layer 14 may be deposited over the semiconductor substrate 10. The interlayer dielectric layer 14 may be comprised of a dielectric material, such as silicon dioxide (SiO₂). Trenches may be formed in the interlayer dielectric layer 14 using lithography and etching that extend from a top surface 13 of the interlayer dielectric layer 14 to the semiconductor substrate 10. The sidewall spacers 20 are formed inside the trenches by depositing a conformal layer of dielectric material with atomic layer deposition (ALD) and etching the deposited conformal layer with a directional etching process, such as reactive ion etching (RIE). The sidewall spacers 20 may be comprised of a low-k dielectric material, such as silicon oxycarbonitride (SiOCN). Following the formation of the sidewall spacers 20, the gate structures 12 may be formed inside the trenches by depositing a series of layers with optional chamfering and planarizing the deposited layers with chemical-mechanical polishing (CMP). The gate dielectric 16 may be comprised of a dielectric material, such as a high-k dielectric material like hafnium oxide (HfO₂) that has a dielectric constant (e.g., permittivity) higher than the dielectric constant of silicon dioxide (SiO₂), deposited by atomic layer deposition (ALD). The gate electrode 18 may include one or more conformal barrier metal layers and/or work function metal layers, such as layers comprised of titanium aluminum carbide (TiAlC) and/or titanium nitride (TiN), and a metal gate fill layer comprised of a conductor, such as tungsten (W), deposited by physical vapor deposition (PVD), chemical vapor deposition (CVD), etc. The barrier metal layers and/or work function metal layers and metal gate fill layer of the gate electrode 18 may be selected for either an n-type field-effect transistor or a p-type field-effect transistor. In an alternative embodiment, the gate structures 12 may be formed by a replacement metal gate process.

Source/drain regions 22 are also arranged in the gaps between adjacent gate structures 12 and below the sections of the interlayer dielectric layer 14. As used herein, the term “source/drain region” means a doped region of semiconductor material that can function as either a source or a drain of a field-effect transistor. For an n-type field-effect transistor, the semiconductor material of the source/drain regions 22 may be doped with an n-type dopant from Group V of the Periodic Table (e.g., phosphorus (P) or arsenic (As)) that is effective to produced n-type conductivity. For a p-type field-effect transistor, the semiconductor material of the source/drain regions 22 may be doped with a p-type dopant selected from Group III of the Periodic Table (e.g., boron (B)) that is effective to produce p-type conductivity. The source/drain regions 22 may be formed by, for example, epitaxial growth of in situ-doped semiconductor material. The source/drain regions 22 are covered by a contact etch stop layer (CESL) 24, which may be constituted by a thin layer of silicon nitride (Si₃N₄).

The device structure that includes the gate structures 12 and source/drain regions 22 may be fabricated during front-end-of-line (FEOL) processing by complementary metal oxide semiconductor (CMOS) processes. The device structure may be, for example, a planar field-effect transistor or a fin-type field-effect transistor.

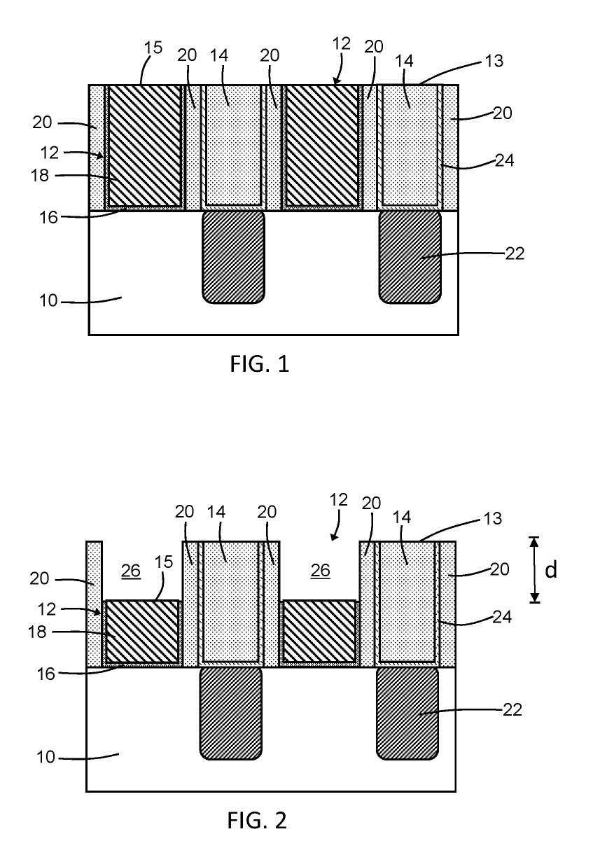

With reference to FIG. 2 in which like reference numerals refer to like features in FIG. 1 and at a subsequent fabrication stage of the processing method, the gate dielectric 16 and gate electrode 18 of the gate structures 12 are etched back and thereby recessed by a distance, d, relative to the interlayer dielectric layer 14, the sidewall spacers 20, and CESL 24. Spaces 26 are respectively opened in an upper portion of the trench above the recessed top surface 15 of the gate structures 12, and the gate electrode 18 of each gate structure 12 is arranged in a lower portion of the trench. Sections of the sidewall spacers 20 and CESL 24 are located above the top surface 15 of the gate structures 12 and are exposed by the etch back of the gate structures 12.

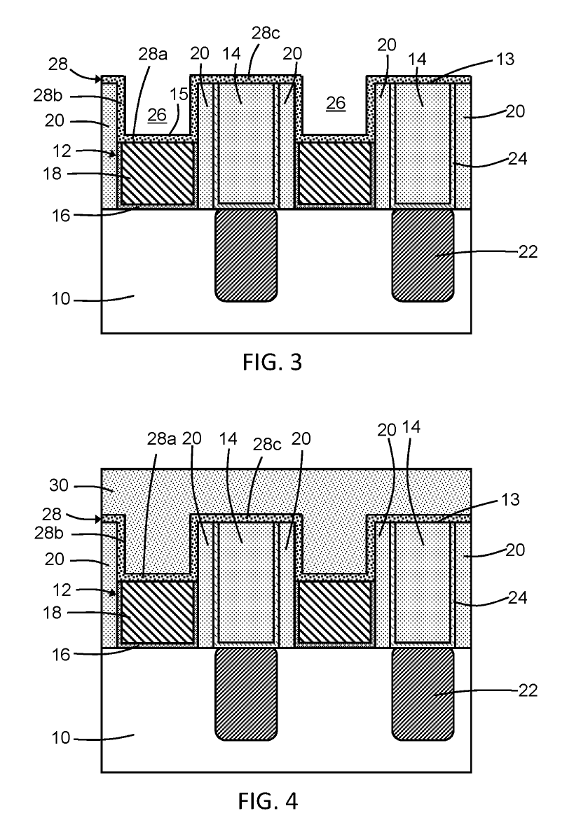

With reference to FIG. 3 in which like reference numerals refer to like features in FIG. 2 and at a subsequent fabrication stage of the processing method, a liner 28 is deposited that includes a horizontal section on the top surface 15 of each gate electrode 18 and vertical sections 28b on the sections of the sidewall spacers 20 that are arranged above the top surface 15 of each gate electrode 18 and that border the corresponding space 26. The liner 28 also includes horizontal sections 28c that are arranged on the top surface 13 of the interlayer dielectric layer 14. The liner 28 may be formed as a conformal layer that may have a uniform thickness and may be comprised of a dielectric material, such as carbon-incorporated silicon oxide (SiOC), titanium oxide (TiO2), hafnium oxide (HfO₂), or aluminum oxide (Al₂O₃), deposited by atomic layer deposition (ALD).

With reference to FIG. 4 in which like reference numerals refer to like features in FIG. 3 and at a subsequent fabrication stage of the processing method, a dielectric layer 30 is deposited as gap-fill material that fills the spaces 26 over the gate electrodes 18 and that has a thickness that is sufficient to cover and bury the gate structures 12 and the field surrounding the gate structures 12. The dielectric layer 30 may be comprised of a dielectric material, such as silicon nitride (Si₃N₄), deposited by chemical vapor deposition (CVD).

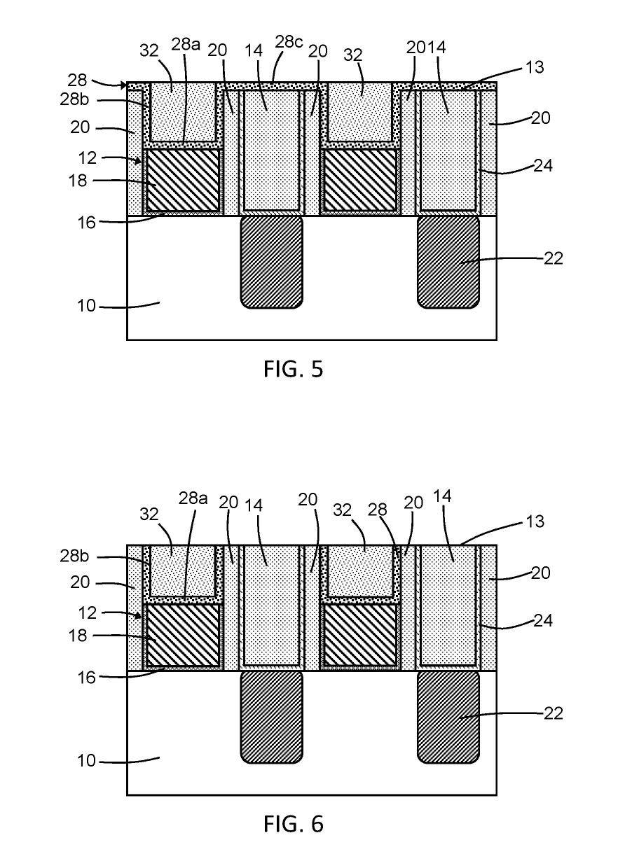

With reference to FIG. 5 in which like reference numerals refer to like features in FIG. 4 and at a subsequent fabrication stage of the processing method, a chemical mechanical polishing (CMP) process may be used to planarize the dielectric layer 30 such that the dielectric layer 30 is removed from the sections 28c of the liner 28 covering the top surface 13 of the interlayer dielectric layer 14. Dielectric caps 32 comprised of the dielectric material of dielectric layer 30 remain inside the spaces 26 in the upper portions of the trenches over the gate structures 12. Material removal during the chemical mechanical polishing process combines abrasion and an etching effect that polishes and removes the targeted materials of the dielectric layer 30. The chemical mechanical polishing process may be conducted with a commercial tool using a polishing pad and a slurry selected to polish the targeted material of the dielectric layer 30 and stop on the material of the liner 28. The material of the liner 28 has a lower removal rate by the chemical mechanical polishing process than the removal rate of either the material of the dielectric layer 30 or the material of the interlayer dielectric layer 14. By operating as a polish stop, the sections 28c of the liner 28 prevent erosion of the material of the interlayer dielectric layer 14, which would have a higher removal rate than the liner 28 if exposed to the chemical mechanical polishing process planarizing the dielectric layer 30.

With reference to FIG. 6 in which like reference numerals refer to like features in FIG. 5 and at a subsequent fabrication stage of the processing method, the sections 28c of the liner 28 over the interlayer dielectric layer 14 are exposed when the dielectric layer 30 is planarized. Following exposure, the sections 28c of the liner 28 are removed from the top surface 13 of the interlayer dielectric layer 14 using a non-selective etching process, such as a non-selective reactive ion etching (RIE) process in which the etch rates of different materials (e.g., the liner 28 and the dielectric caps 32) are equal or approximately equal.

Processing continues by removing the sections of the interlayer dielectric layer 14 from the gaps between the gate structures 12 with self-aligned contact (SAC) etching that forms contact openings extending to the source/drain regions 22, and filling the contact openings with a conductor, such as a metal silicide, to form contacts coupled with the source/drain regions 22. The device structure may be either a long channel device or a short channel device

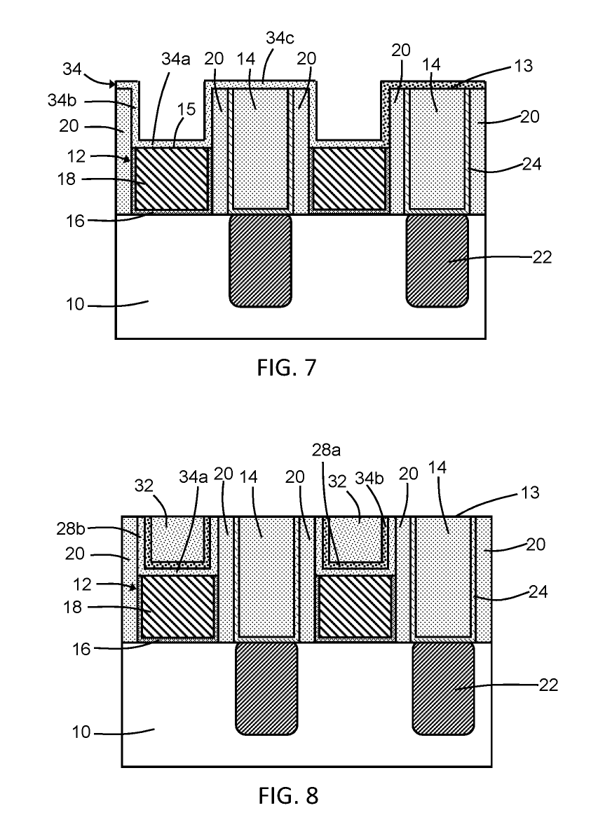

With reference to FIG. 7 in which like reference numerals refer to like features in FIG. 2 and at a subsequent fabrication stage of a processing method in accordance with alternative embodiments, a liner 34 may be formed, prior to the formation of the liner 28, that includes a horizontal section 34a on the top surface 15 of each gate structure 12 and vertical sections 34b on the sections of the sidewall spacers 20 that are arranged above the top surface 15 and that border the corresponding space 26. The liner 34 also includes horizontal sections 34c that are arranged on the top surface 13 of the interlayer dielectric layer 14. The liner 34 may be formed as a conformal layer and may be comprised of a dielectric material, such as silicon nitride (Si₃N₄), deposited by atomic layer deposition (ALD).

With reference to FIG. 8 in which like reference numerals refer to like features in FIG. 7 and at a subsequent fabrication stage of the processing method, processing continues with the deposition of the liner 28 on the liner 34 and the deposition of the dielectric layer 30, following by planarization to form the dielectric caps 32. The sections 34c of the liner 34, as well as the sections 28c of the liner 28, arranged over the top surface 13 of the interlayer dielectric layer 14 are removed by the non-selective etching process in which the materials of the liner 28, the dielectric caps 32, and the liner 34 are removed with nominally equal etch rates. The horizontal section of the liner 34 is arranged between the horizontal section of the liner 28 and the gate electrode 18, and the vertical sections of the liner 34 are arranged between the vertical sections of the liner 28 and the sidewall spacers 20.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the “horizontal”, as just defined. The term “lateral” refers to a direction within the horizontal plane. Terms such as “above” and “below” are used to indicate positioning of elements or structures relative to each other as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1-12. (canceled)

13. A structure comprising:
a semiconductor substrate having a top surface;
a gate electrode disposed on the top surface of the semiconductor substrate, the gate electrode having a top surface;
a plurality of sidewall spacers including respective sections located above the top surface of the gate electrode, the respective sections of the sidewall spacers providing a border for a space arranged over the top surface of the gate electrode;
a first liner disposed in the space over the top surface of the gate electrode, the first liner comprised of a dielectric material; and
a dielectric cap disposed in the space over the first liner,
wherein the first liner is a conformal layer that includes a horizontal section on the top surface of the gate electrode and respective vertical sections on the respective sections of the sidewall spacers.

14. The structure of claim 13 wherein the first liner is comprised of carbon-incorporated silicon oxide, titanium oxide, hafnium oxide, or aluminum oxide, and the dielectric cap is comprised of silicon nitride.

15-16. (canceled)

17. The structure of claim 13 further comprising:
a second liner in the space over the top surface of the gate electrode.

18. The structure of claim 17 wherein the first liner is comprised of carbon-incorporated silicon oxide, titanium oxide, hafnium oxide, or aluminum oxide, and the dielectric cap and the second liner are comprised of silicon nitride.

19. The structure of claim 17 wherein the second liner is a conformal layer that includes a horizontal section between the horizontal section of the first liner and the top surface of the gate electrode and respective vertical sections between the respective vertical sections of the first liner and the respective sections of the sidewall spacers.

20. (canceled)

21. The structure of claim 13 further comprising:
a first source/drain region; and
a second source/drain region,
wherein the gate electrode is laterally arranged between the first source/drain region and the second source/drain region.

22. The structure of claim 21 further comprising:
an interlayer dielectric layer including a first section over the first source/drain region and a second section over the second source/drain region.
